(19) United States
(12) Patent Application Publication
(10) Pub. No.: US 2009/0136049 A1
(43) Pub. Date: May 28, 2009

(54) Device and method for acoustic communication and/or perception in a motor vehicle

(75) Inventor: Holger Opfer, Hannover (DE)

Correspondence Address: KENYON & KENYON LLP, ONE BROADWAY, NEW YORK, NY, 10004, US

(73) Assignee: VOLKSWAGEN AG, Wolfsburg (DE)

(21) Appl. No.: 11/664,752

(22) PCT Filed: Sep. 28, 2005
(86) PCT No.: PCT/EP05/10632

§ 371 Date: Apr. 14, 2008

(30) Foreign Application Priority Data
Oct. 4, 2004 (DE) 10 2004 048 988.2
Oct. 4, 2004 (DE) 10 2004 048 989.0

(51) Int. Cl. H03G 3/20; H04B 1/00

(52) U.S. Cl. 381/57; 381/86

(57) ABSTRACT

A device for acoustic communication and/or perception in a motor vehicle includes at least one microphone and at least one loudspeaker, which are assigned to a vehicle seat, the microphones taking the form of directional microphones, the at least one loudspeaker taking the form of a directional loudspeaker. A method is for improving the acoustic communication and/or perception in a motor vehicle.

### FIELD OF THE INVENTION

The present invention relates to a device and a method for acoustic communication and/or perception in a motor vehicle.

### BACKGROUND INFORMATION

Loudspeaker systems in a motor vehicle are used primarily for emitting audio signals. The audio signal sources are, for instance, radios, CD players, MP3 players or DVD players. In addition, the loudspeakers are increasingly used for emitting acoustic information, for example, of a navigation system and/or a parking assistance system and/or a hands-free speaking system.

Conventional loudspeakers in a motor vehicle are constructed as electrodynamic loudspeakers having permanent magnets. These are relatively voluminous and heavy, which, because of the limited available space in a motor vehicle, often results in compromises between installation location and emission characteristics.

A planar loudspeaker is described in Japanese Published Patent Application No. 2004-56564, which is situated behind the roofliner, so that there is a greater degree of freedom with regard to size and shape.

An acoustic element described in PCT International Published Patent Application No. WO 99/56498, including at least two porous layers, which are electrically conductive or are metallized on one side. Between the two porous layers, an insulated plastic layer is situated, which preferably takes the form of two layers, a metallic coating existing between the two layers, via which the plastic layer can be charged to a certain electrical potential. The plastic layer is connected to the porous layers at certain places. Between two such joints there is an air gap between the porous layers and the plastic layer. By applying a signal to at least one porous layer, the plastic layer is then set into vibration, the other porous layer preferably also having the signal in phase opposition applied to it. This system represents an electrostatic planar loudspeaker.

A method is described in German Published Patent Application No. 199 58 836 for improving communication in a vehicle, the voice signals of the occupants of a vehicle being picked up individually for each occupant via a microphone assigned to him within the scope of his seat; the picked up voice signals being amplified separately for each occupant in an input stage and being filtered for start level minimization and frequency adjustment; the amplified and filtered voice signals of each individual occupant being subjected to a signal processing, individual for each output channel, in the form of a propagation time correction and a level differentiation for distribution to the output channels and thus for distribution to the individual components of a voice output device made up of loudspeakers, as a function of the local assignment of the microphone in the vehicle, via which the voice signal was picked up, and as a function of the local assignment of each individual loudspeaker of the voice output device in the vehicle, via which the voice signal is to be output, via a summation stage and a distribution stage, and the assignment of the voice signal individually processed for each output channel to the individual output channels and thus to the individual loudspeakers of the voice output device occurring via an adjustment stage, in which, via a level adjustment and a frequency adjustment, an adjustment is performed, adapted to each output channel and thus to each loudspeaker of the voice output device, of the respective voice signal to the spatial conditions of the vehicle and the desired volume. For this purpose, the microphones may take the form of directional microphones. Furthermore, a use as a telephone device having a free assignment of users within the vehicle is provided. When used in the context of telephone processes, the structure of the device makes it possible to assign a conversation, for example, to each seat and thus to each occupant. In this context, the reproduction may be controlled via selected loudspeakers, so that that it is also possible to engage selected vehicle occupants in the telephone conversation. At the same time, it is possible to limit the ability to listen in on a conversation in certain seats. This is done by switching the incoming signal to appropriately selected loudspeakers and by treating it as a fictive or virtual voice source. The outgoing signal(s) undergo(es) the same process as the signal which is utilized for the internal communication. operating units of the control unit may be used to exclude certain seats or areas both from the pick-up end as well as from the reproduction end.

### SUMMARY

Example embodiments of the present invention may provide a device for acoustic communication and/or perception in a motor vehicle and may provide suitable methods for this purpose.

To this end, the loudspeaker takes the form of a directional loudspeaker. The crosstalk from the loudspeaker to another vehicle seat is thereby already considerably minimized. This in turn increases the quality of the acoustic perception, for example, of music, but also of voice signals from other vehicle seats such that painstaking propagation delay adjustments and level adjustments are not required. A directional loudspeaker includes an acoustic source which emits sound differently in different spatial directions, the direction of the strongest emission (major lobe) being designated by an angle of 0°. The quality of a directional emitter or directional loudspeaker is generally determined by a planar extension of the emitter compared to the wavelength of the frequencies in question. One possible characteristic of the directional loudspeaker is that, for frequencies whose wavelength is less than the extension of the emitter at right angles to the alignment of the emitter, all minor lobes of the directional characteristic deviating above 45° from the alignment of the emitter are less by at least −10 dB.

The device may take the form of a hands-free speaking system. This makes it so that the emitted acoustic signals are substantially heard only by the active participants of the telephone conversation. This makes it possible to conduct a private telephone call in a motor vehicle without the other vehicle occupants being able to or being forced to listen in.

At least two vehicle seats may be respectively assigned one loudspeaker and one microphone, which can be controlled by a control unit, such that a communication is supported between individual vehicle seats or individual vehicle seats are blocked from the communication.

The directional loudspeaker may take the form of at least one electrostatic planar loudspeaker. This may provide that, compared to conventional electrodynamic loudspeakers, it is extremely flat, and, because of this and based on the materials used, it is easily flexible, which simplifies integration into structural parts of the vehicle. Moreover, the emission characteristic is narrower. A further aspect is that the planar loudspeaker, which is not actively driven, acts automatically as a damper for high frequencies greater than 1 kHz, for instance, and thus dampens interfering noises.

The electrostatic planar loudspeaker may include at least two porous layers, which are electrically conductive or metallized on one side, an insulated plastic layer being situated between the porous layers, which can be charged to a certain electric potential and is connected in certain places to the porous layers. In addition, the plastic layer may be made up of two layers, a metal coating existing between the two layers.

The loudspeaker system may be formed by at least two adjacent planar loudspeakers, which can be controlled by different complex transmission functions for setting an emission characteristic. This allows for the emission characteristic to be considerably improved, especially at low frequencies, since otherwise minor lobes may result at low frequencies, which would lead to crosstalk to adjacent vehicle seats. Using the complex transmission functions, by contrast, a directional loudspeaker can be set over the entire audio frequency. In this context, the complex transmission functions can be permanently set or can be changed adaptively in order to set an emission characteristic adapted to the respective conditions with respect to opening angle and/or direction.

The various planar loudspeakers are arranged concentrically about one another, so that an emission characteristic can be set that is symmetrical about the emission direction, which may have a very low opening angle. For this purpose, the planar loudspeakers are designed either as rings or as rectangles or squares that are arranged around one another.

Alternatively, the planar loudspeakers can be positioned side by side in the form of strips so as to avoid at least lateral crosstalk. An aspect of this arrangement is the simple design.

The directional microphone may take the form of an electrostatic planar microphone, the reader being referred to the explanations for the planar loudspeaker with respect to its characteristics. For this purpose, a property of electrostatic loudspeakers can be utilized, namely, that relatively simply they can also be operated as microphones. If no signal voltage is actively applied to the porous layers, a sound wave produces a deflection of the plastic layer, which results in a voltage change at the electrodes of the porous layers, which can be picked off as a signal voltage.

On account of the reciprocity theorem, the receiving characteristic of the directional microphone can also be improved further by using multiple planar microphones, which can be controlled by different complex receiving functions for setting a receiving characteristic.

The planar microphones may be concentrically with respect to one another.

At least two planar loudspeakers arranged side by side can be alternatively operated as stereo loudspeakers or as directional loudspeakers. In this instance, the user is able to select whether he would rather have stereo sound in the case of music reproductions, for example, or a good directional characteristic so as not to disturb the other vehicle occupants.

The directional microphones and/or directional loudspeakers may be integrated into the roofliner.

The directional microphones and/or the directional loudspeakers may be integrated into the roofliner using a quick-change frame, the two panel sides of a directional loudspeaker and/or a directional microphone optionally having different themes. This makes use of the electrostatic panels being designed symmetrically. Using the different themes, one theme may, for instance, be adapted to the roofliner, whereas the other may feature children's decoration.

The roofliner itself may be formed from the panel material of the planar loudspeakers and/or planar microphones. Areas of the panel may then be defined as loudspeakers, microphones or supply lines by appropriate patterns. The roofliner thus becomes a multifunctional element. The porous layer may be arranged as an insulator, which is metallized on the side facing the plastic layer. Consequently there is no voltage present on the side of the roofliner facing the occupant cell.

Individual acoustic signals may be supplied to the individual directional loudspeakers of the vehicle seats. Thus, for example, music may be fed to one vehicle seat via its directional loudspeaker, and a radio drama may be fed to another vehicle seat via its directional loudspeaker. Because of the directional loudspeakers, crosstalk to the other vehicle seats is low in this instance.

The crosstalk noises from other vehicle seats may be masked or extinguished by additional acoustic signals. This may happen in that the cross talk is measured and/or estimated, a signal in phase opposition to the crosstalk then being emitted. In a development as a hands-free speaking system, for example, it is thus possible to assign the hands-free speaking system for the telephone connection optionally to one or several vehicle seats simultaneously or to forestall the ability to listen in entirely. An input unit can be used to select which vehicle seat(s) are to be engaged in the telephone connection.

An acoustic channel may be set between two vehicle seats. In this context, an acoustic channel signifies that the signals picked up by a directional microphone of a first vehicle seat are emitted only via a directional loudspeaker of a second vehicle seat and vice versa.

The other vehicle seats may disengaged from the communication by interfering or extinguishing or masking signals. This makes it possible to operate a kind of secret mode, i.e., two persons are able to converse in the motor vehicle without the others being able to listen in. Crosstalk to the other vehicle seats that possibly still exists is then actively extinguished by emitting signals that are in phase opposition to the crosstalk or masked by playing background noises or music. For improving the directional characteristic, a high-pass filter may additionally be provided in the audio processor or in the control unit, by which the low frequencies that are harder to direct are filtered out such that the quality of the secret mode is improved further.

When implementing an acoustic channel, a level of ambient noises may be measured by the control unit or a suitable sensor system, the volume and/or frequency response of the acoustic signals of the directional loudspeakers being adapted in the acoustic signal to the level of the ambient noises.

For implementing an acoustic channel in the secret mode, the acoustic channel may be activated by an input, the acoustic signals at a first vehicle seat engaged in the acoustic channel then also being picked up by the directional microphone associated with the vehicle seat at least when setting up the secret mode, the picked up signal being emitted in an amplified manner via the associated directional loudspeaker and being emitted at an adapted volume via the directional loudspeaker of the other vehicle seat engaged in the acoustic channel. The two participants are hereby urged to whisper since people usually speak more quietly if they hear their voices very loudly. On the other hand, when speaking, one usually adjusts to the volume of the communicating partner such that the conversation partner is himself urged by the adapted volume of the reproduction to speak quietly. This procedure may also be followed in the other direction.

This method may be repeated until the output levels on the directional loudspeakers of the acoustic channel are in a certain proportion to a detected and/or estimated background noise.

Example embodiments of the present invention are described in more detail below with reference to the appended Figures.

### BRIEF DESCRIPTION OF THE DRAWINGS

FIG. 1 is a schematic representation of a directional loudspeaker and a directional microphone for a vehicle seat.

FIG. 2 is a schematic representation of the acoustic distribution in a first mode.

FIG. 3 is a schematic representation with an acoustic channel between two vehicle seats.

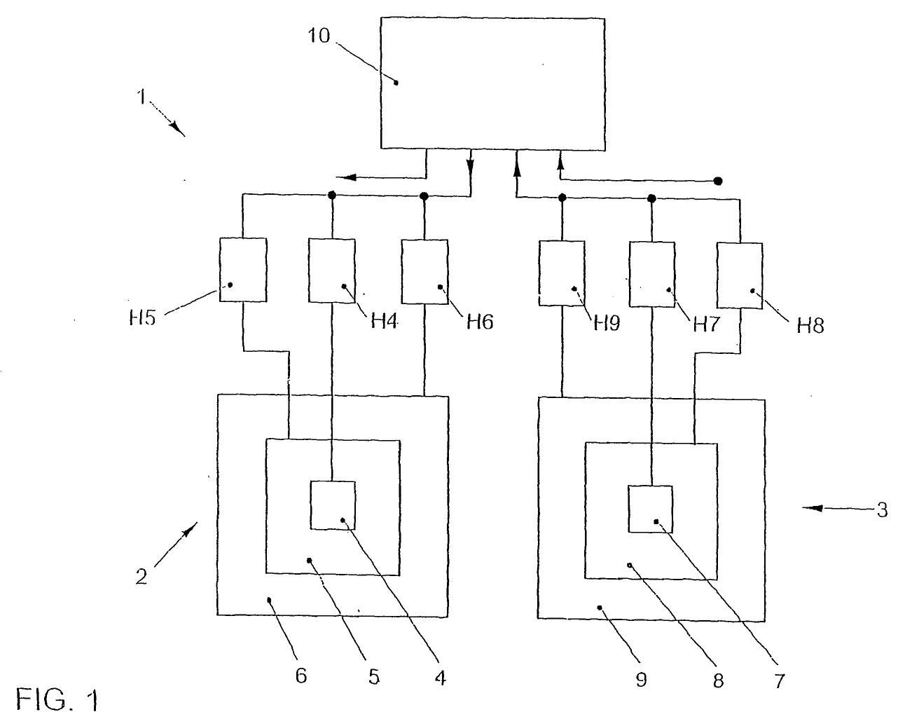

### DETAILED DESCRIPTION

Device 1 includes a directional loudspeaker 2 and a directional microphone 3. Directional loudspeaker 2 is made up of three electrostatic planar loudspeakers 4-6. Directional microphone 3 is made up of three electrostatic planar microphones 7-9. One complex transmission function H4(f)-H6(f) is assigned to each of the planar loudspeakers 4-6. Correspondingly, one complex receiving function H7(f)-H9(f) is assigned to each of the planar microphones 6-8. The three respective planar loudspeakers 4-6 and planar microphones 7-9 are concentrically arranged with respect to one another. Device 1 furthermore includes an audio processor 10. Beam forming may be achieved via complex transmission functions H4(f)-H6(f) such that minor lobes of directional loudspeaker 2 are minimized. The same applies to receiving functions H7(f)-H9(f) of directional microphone 3. These are selected such that a very narrow major lobe results for the emission and receiving characteristics with respect to the associated vehicle seat. As indicated by the additional inputs and outputs on audio processor 10, additional directional loudspeakers and directional microphones assigned to other vehicle seats are triggered. For this purpose, the audio processor also represents a control unit for the directional loudspeakers and directional microphones. In an arrangement as a hands-free speaking system, the device includes a telecommunication module, which takes the form of a GSM module, for example, and which is connected to audio processor 10, it also being possible for the audio processor to be integrated into the telecommunication module. The additional vehicle seats may either also be engaged into the telephone connection or an interfering signal or an additional signal such as music, for example, is played over their directional loudspeakers.

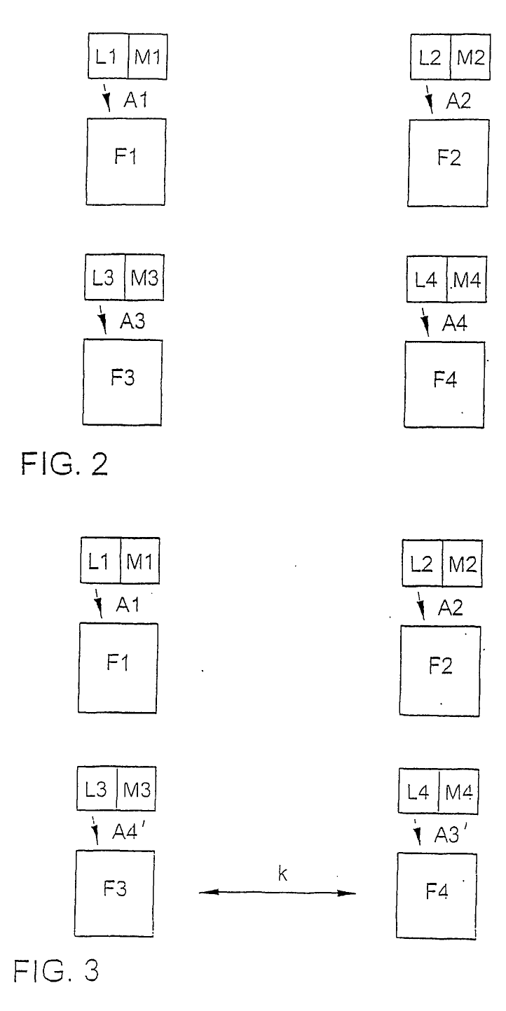

FIG. 2 shows an arrangement, in which one directional loudspeaker L1-L4 and one directional microphone M1-M4 are assigned to each vehicle seat F1-F4. Since the crosstalk to the other vehicle seats is very low on account of directional loudspeakers L1-L4, an individual audio signal A1-A4 may be supplied to each vehicle seat F1-F4 via the directional loudspeakers without these interfering with one another. Thus, information of a navigational system may be indicated via directional loudspeaker L1, for example, while the other directional loudspeakers L2-L4 reproduce music and/or radio plays. To reduce crosstalk further, the individual directional loudspeakers L1-L4 may additionally emit interfering signals, which are respectively in phase opposition to the crosstalk.

Thus, for example, the audio processor may estimate what crosstalk directional loudspeakers L2-L4 generate on vehicle seat Fl. For this purpose, for example, transmission functions between the individual vehicle seats F1-F4 are determined in advance and stored. Since the audio processor recognizes the individual audio signals A1-A4, the respective crosstalk may then be determined. Accordingly, this determination may be made online in that the crosstalk is detected via directional microphones M1-M4.

FIG. 3 shows the implementation of an acoustic channel K between vehicle seats F3 and F4. In this instance, two modes are to be distinguished, that is, a dialogue mode and a “secret mode”.

The arrangement of an acoustic channel may be initiated by various events, for example, by an input or an automatic detection of a dialogue started between two vehicle seats. The basic principle of acoustic channel K is that the acoustic signals on vehicle seat F3 are picked up by directional microphone M3 and are output by directional loudspeaker L4 as audio signal A3′ and vice versa. The two other vehicle seats F1 and F2 in this instance receive audio signals A1 and A2, for example, music. It is not necessary, however, to emit audio signals A1 and A2. For improving the acoustic quality of acoustic channel K, there may be an additional provision to determine the crosstalk from vehicle seats F1 and F2 to vehicle seats F3 and F4 and to indicate in each case a crosstalk signal in phase opposition additionally compensating for the crosstalk via directional loudspeakers L3 and L4. Alternatively or additionally, the low frequencies to 200 Hz, for example, may be filtered out from the acoustic channel.

In the already mentioned secret mode, in addition to described acoustic channel K, provision is made to ensure that no crosstalk occurs from vehicle seats F3 and F4 to vehicle seats F1 and F2. To this end, there is again the possibility of determining or estimating the crosstalk, signals in phase opposition to the crosstalk being then emitted via directional loudspeakers L1, L2. Alternatively or additionally, music or amplified background noises may be emitted, which mask the crosstalk. To optimize this secret mode, directional microphone M3 first picks up an audio signal on vehicle seat F3. This audio signal is then amplified via L3 and is output via L4 at an adapted volume. Urged to speak more quietly by the vehicle occupant on vehicle seat F3 on account of one's own loud voice, whereas the vehicle occupant on vehicle seat F4 by contrast is encouraged to whisper. The transmission from vehicle seat F4 to vehicle seat F3 occurs accordingly. For this purpose, the levels for the amplification or the adapted volume are set in relation to the background noises such that a relaxed secret dialogue can take place, which cannot be eavesdropped upon. For example, therefore, the level of the background noises is measured and the factors are set relative to the level. Furthermore, the distances between the directional loudspeaker, the directional microphone and the person can also be taken into account for this purpose. In addition, the low frequencies to approximately, e.g., 200 Hz may again be filtered out.

1 to 29. (canceled)

30. A device for at least one of (a) acoustic communication and (b) acoustic perception in a motor vehicle, comprising:
at least one directional microphone corresponding to each vehicle seat of the motor vehicle; and
at least one directional loudspeaker corresponding to each vehicle seat of the motor vehicle.

31. The device according to claim 30, wherein the device is arranged as a hands-free speaking system.

32. The device according to claim 30, wherein at least two vehicle seats respectively correspond to one loudspeaker and one microphone, the device further comprising a control unit configured to at least one of (a) support a communication between individual vehicle seats and (b) block individual seats from the communication.

33. The device according to claim 30, wherein the directional loudspeaker is arranged as at least one electrostatic planar loudspeaker.

34. The device according to claim 33, wherein the electrostatic planar loudspeaker includes at least two porous layers at least one of (a) electrically conductive and (b) metallized on one side, an insulated plastic layer arranged between the porous layers, chargeable to a certain electric potential and connected in certain places to the porous layers.

35. The device according to claim 34, wherein the plastic layer includes two layers and a metal coating arranged between the two layers.

36. The device according to claim 33, wherein the directional loudspeaker includes at least two adjacent planar loudspeakers controllable by different complex transmission functions to set an emission characteristic.

37. The device according to claim 36, wherein the planar loudspeakers are arranged at least one of (a) concentrically with respect to one another and (b) side by side in the form of strips.

38. The device according to claim 30, wherein the directional microphone is arranged as an electrostatic planar microphone.

39. The device according to claim 38, wherein the directional microphone includes at least two adjacent electric planar microphones controllable by different complex receiving functions to set a reception characteristic.

40. The device according to claim 39, wherein the planar microphones are arranged concentrically with respect to one another.

41. The device according to claim 36, wherein the at least two planar loudspeakers arranged side by side are operable alternatively as (a) stereo loudspeakers and (b) directional loudspeakers.

42. The device according to claim 30, wherein at least one of (a) the directional microphones and (b) the directional loudspeakers are integrated into a roofliner.

43. The device according to claim 42, wherein the at least one of (a) the directional microphones and (b) the directional loudspeakers are integrated into the roofliner WITH a quick-change frame, two panel sides of at least one of (a) the directional loudspeaker and (b) the directional microphone having different themes.

44. The device according to claim 42, wherein the roofliner is made of a panel material of at least one of (a) an electrostatic planar loudspeaker and (b) a planar microphone.

45. The device according to claim 44, wherein the panel material is structured to define regions as at least one of (a) directional microphones, (b) directional loudspeakers and (c) supply lines.

46. The device according to claim 30, wherein individual acoustic signals are suppliable to individual directional loudspeakers of the vehicle seats.

47. The device according to claim 46, wherein crosstalk noises from other vehicle seats are at least one of (a) maskable and (b) extinguishable by additional acoustic signals.

48. The device according to claim 32, wherein an acoustic channel is settable between two vehicle seats.

49. The device according to claim 48, wherein other vehicle seats are disengaged from the communication by at least one of (a) interference and (b) masking signals.

50. A method for at least one of (a) acoustic communication and (b) acoustic perception in a motor vehicle, comprising:
supplying individual acoustic signals to individual directional loudspeakers, of a device, corresponding vehicle seats of the motor vehicle, the device including at least one directional microphone corresponding to each vehicle seat of the motor vehicle and at least one directional loudspeaker corresponding to each vehicle seat of the motor vehicle.

51. The method according to claim 50, further comprising at least one of (a) masking and (b) extinguishing crosstalk noises from other vehicle seats by additional acoustic signals via the directional loudspeaker.

52. A method for at least one of (a) acoustic communication and (b) acoustic perception in a motor vehicle, comprising:
establishing an acoustic channel between at least to vehicle seats of the motor vehicle with a device that includes at least one directional microphone corresponding to each vehicle seat of the motor vehicle and at least one directional loudspeaker corresponding to each vehicle seat of the motor vehicle.

53. The method according to claim 52, further comprising:
measuring, by a control unit, a level of ambient noises; and
adapting at least one of (a) a volume and (b) a frequency response of acoustic signals of the directional loudspeakers in the acoustic channel to the level of the ambient noises.

54. The method according to claim 52, further comprising:
at least one of measuring and estimating crosstalk from the vehicle seats engaged in the acoustic channel to other vehicle seats; and
at least one of extinguishing and masking the crosstalk with acoustic signals emitted via the directional loudspeakers of the other vehicle seats.

55. The method according to claim 54, further comprising activating the method by an input.

56. The method according to claim 55, further comprising:
picking up an acoustic signal on a first vehicle seat engaged in the acoustic channel by the directional microphone corresponding to the first vehicle seat;
emitting the picked-up acoustic signal amplified via the directional loudspeaker corresponding to the first vehicle seat; and
emitting the picked-up acoustic signal at an adapted volume via the directional loudspeaker corresponding to a second vehicle seat engaged in the acoustic channel.

57. The method according to claim 56, further comprising repeating the method for acoustic signals of the second vehicle seat engaged in the acoustic channel.

58. The method according to claim 56, further comprising repeating the method until output levels on the directional loudspeakers of the acoustic channel are in a certain proportion to at least one of (a) a detected and (b) an estimated background noise.
